(19) United States
(12) Patent Application Publication
(10) Pub. No.: US 2007/0231998 A1
(43) Pub. Date: Oct. 4, 2007

(54) Method for preparing a capacitor structure of a semiconductor memory

(75) Inventors: Yu Chi Chen, Hsinchu (TW); Neng Hui Yang, Hsinchu (TW); Hsi Chieh Chen, Jhubei (TW)

Correspondence Address: OLIFF & BERRIDGE, PLC, P.O. BOX 19928, ALEXANDRIA, VA, 22320, US

(73) Assignee: PROMOS TECHNOLOGIES INC., Hsinchu (TW)

(21) Appl. No.: 11/438,396

(22) Filed: May 23, 2006

(30) Foreign Application Priority Data
Apr. 4, 2006 (TW) 095111892

(51) Int. Cl. H01L 21/8242

(52) U.S. Cl. 438/253; 438/396

(57) ABSTRACT

A method for preparing a capacitor structure comprises forming an opening in a dielectric structure, and forming a cylindrical capacitor including a first conductive layer on the sidewall of the opening, a first dielectric layer on the surface of the first conductive layer, and a second conductive layer on the surface of the first dielectric layer. A top portion of the first conductive layer is selectively removed, and a predetermined portion of the dielectric structure is removed. A second dielectric layer covering the cylindrical capacitor and the dielectric structure is then formed to electrically separate the first conductive layer from the second conductive layer. Subsequently, a portion of the second dielectric layer is removed from the top surface of the second conductive layer, and a third conductive layer is formed on the second dielectric layer and the top surface of the second conductive layer.

### BACKGROUND OF THE INVENTION

(A) Field of the Invention

The present invention relates to a method for preparing a capacitor structure of a semiconductor memory, and more particularly, to a method for preparing a capacitor structure of a semiconductor memory, which is suitable for application to high integrity fabrication processes.

(B) Description of the Related Art

A memory cell of the DRAM generally consists of a metal oxide semiconductor field effect transistor (MOSFET) and a capacitor, and the transistor includes a source electrode electrically connected to a bottom electrode of the capacitor. There are two types of capacitors: stacked capacitors and deep trench capacitors. The stacked capacitor is fabricated on the surface of a silicon substrate, while the deep trench capacitor is fabricated inside the silicon substrate.

FIG. 1 and FIG. 2 illustrate a method for preparing a stacked capacitor 22 according to the prior art. The method forms a semicrown-shaped bottom electrode 20′, and a dielectric layer 24 is then formed on the semicrown-shaped bottom electrode 20′, wherein the semicrown-shaped bottom electrode 20′ is hollow. Subsequently, an upper electrode 26 is formed on the dielectric layer 24 to complete the stacked capacitor 22. The integrity of the dynamic random access memory increases rapidly with continuous improvements in the semiconductor fabrication process, but the lateral width of the capacitor must be decreased to achieve the high integrity. However, decreasing the lateral width results in reduced size of the surface area, i.e., a reduced capacitance, which is proportional to the surface area.

To maintain or increase the capacitance of the capacitor, researchers increase the vertical height and decrease the lateral width of the capacitor to increase the size of the surface area of the capacitor, i.e., increase the aspect ratio of the capacitor in response to the decreased lateral width of the capacitor for achieving high integrity. However, achieving the objective of high integrity by increasing the aspect ratio of the capacitor creates an arduous problem, i.e., the hollow semicrown-shaped bottom electrode 20′, referring to FIG. 1, is likely to lean or even collapse due to insufficient mechanical supporting strength during the fabrication process.

To solve the problem of insufficient mechanical supporting strength, D. H. Kim et al. disclose a method for preparing a mechanical strength enhanced storage node (see “A mechanically enhanced storage node for virtually unlimited height (MESH) capacitor aiming at sub 70 nm DRAMs”, IEDM, 04, p 69-72). However, the method disclosed by D. H. Kim et al. is quite complicated, and increases the fabrication difficulty.

### SUMMARY OF THE INVENTION

One object of the present invention provides a method for preparing a capacitor structure of a semiconductor memory, which can prevent the cylindrical capacitor from leaning or collapsing due to insufficient mechanical supporting strength, and therefore is applicable to high integrity fabrication processes.

A method for preparing a capacitor structure of a semiconductor memory according to one aspect of the present invention forms an opening in a dielectric structure at first. A first conductive layer, a first dielectric layer and a second conductive layer are then formed in sequence on the sidewall of the opening to form a cylindrical capacitor in the opening. Subsequently, an etching process is performed to remove a top portion of the first conductive layer such that a top end of the first conductive layer is lower than that of the second conductive layer, and a predetermined portion of the dielectric structure is removed. A second dielectric layer is formed on the surfaces of the cylindrical capacitor and the dielectric structure, a portion of the second dielectric layer is selectively removed from the second conductive layer, and a third conductive layer is then formed on the second dielectric layer and on the top end of the second conductive layer to electrically connect with the second conductive layer.

Another aspect of the present invention provides a method for preparing a capacitor structure of a semiconductor memory, in which a predetermined portion of the dielectric structure is removed and a dry etching process is performed to remove the top portion of the first conductive layer such that a spacer profile is formed on a top portion of the cylindrical capacitor after the cylindrical capacitor is formed in the opening of the dielectric structure. Subsequently, a second dielectric layer is formed on the surfaces of the cylindrical capacitor and the dielectric structure, a portion of the second dielectric layer is selectively removed from the second conductive layer, and a third conductive layer is then formed on the second dielectric layer and on the top end of the second conductive layer to electrically connect the second conductive layer.

Preferably, the cylindrical capacitor is a solid cylinder filling the opening. The first conductive layer and the second conductive layer are made of different materials, and the top portion of the first conductive layer is removed by an etching process, of which etching rate to the first conductive layer is higher than that to the second conductive layer.

The conventional hollow semicrown-shaped bottom electrode is likely to lean or even collapse due to insufficient mechanical supporting strength during the fabrication process. In contrast, the method of the present invention forms a solid cylindrical capacitor filling the opening in the dielectric structure, and the solid cylindrical capacitor possesses enough mechanical supporting strength after a predetermined portion of the dielectric structure is removed. Consequently, the solid cylindrical capacitor will not lean or collapse during the subsequent fabrication process, and the method of the present invention is suitable for application to the high integrity fabrication process.

### BRIEF DESCRIPTION OF THE DRAWINGS

The objectives and advantages of the present invention will become apparent upon reading the following description and upon reference to the accompanying drawings in which:

FIG. 1 and FIG. 2 illustrate a method for preparing a stacked capacitor according to the prior art;

FIG. 3(a) to FIG. 11 illustrate a method for preparing a capacitor structure of a semiconductor memory according to a first embodiment of the present invention; and

FIG. 12 to FIG. 15 illustrate a method for preparing a capacitor structure according to a second embodiment of the present invention.

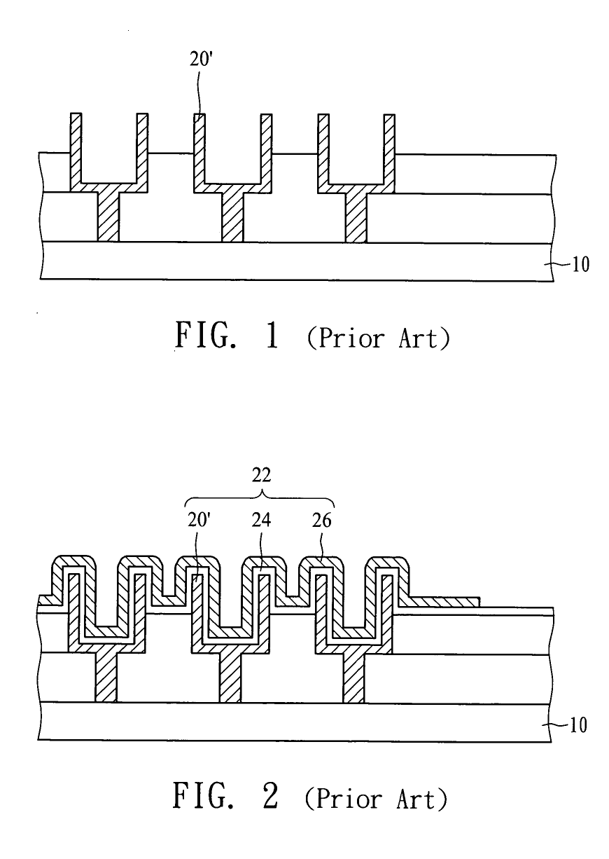

### DETAILED DESCRIPTION OF THE INVENTION

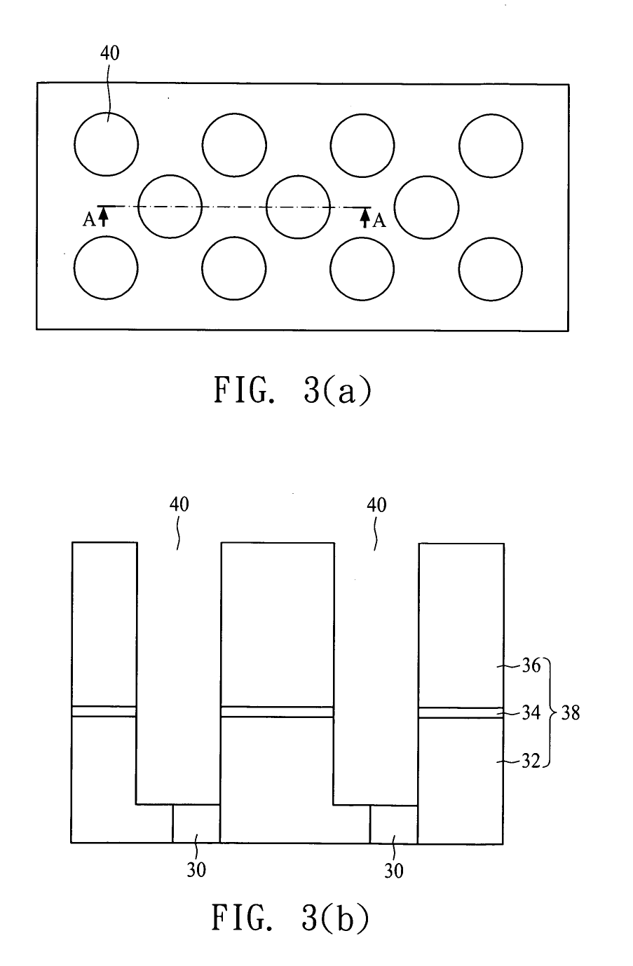

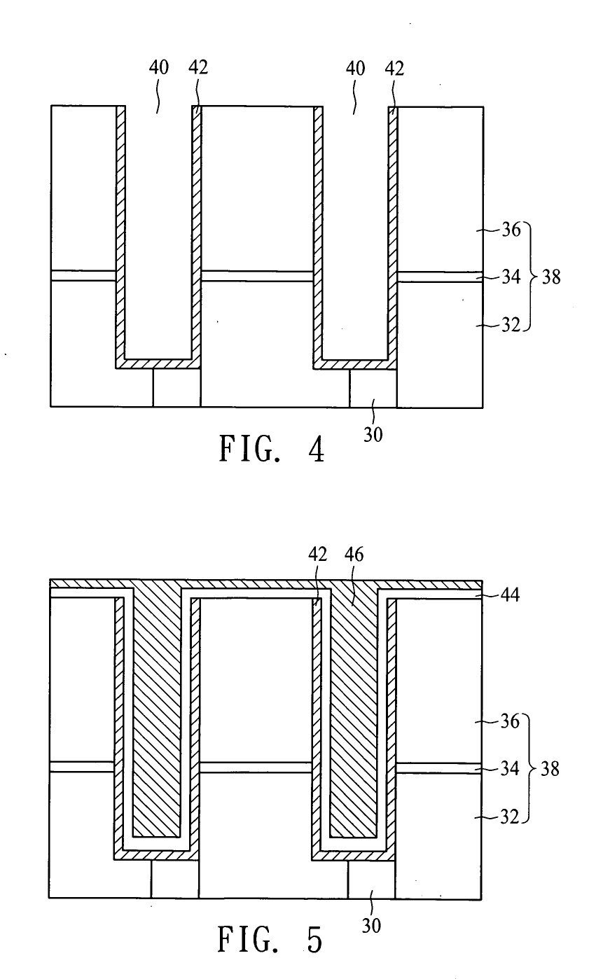

FIG. 3(a) to FIG. 11 illustrate a method for preparing a capacitor structure 60 of a semiconductor memory according to a first embodiment of the present invention, wherein FIG. 3(b) to FIG. 11 are cross-sectional diagrams along a cross-section line A-A in FIG. 3(a). A circular opening 40 is formed in a dielectric structure 38 including a silicon oxide layer 32, a silicon nitride layer 34 positioned on the silicon oxide layer 32 and a silicon oxide layer 36 positioned on the silicon nitride layer 34; wherein a contact plug 30 is formed in the silicon oxide layer 32 in advance. Subsequently, a deposition process and an etching back process are performed to form a first conductive layer 42 made of titanium nitride (TiN), tantalum nitride (TaN), ruthenium (Ru) or doped polysilicon on the inner sidewall of the circular opening 40, as shown in FIG. 4.

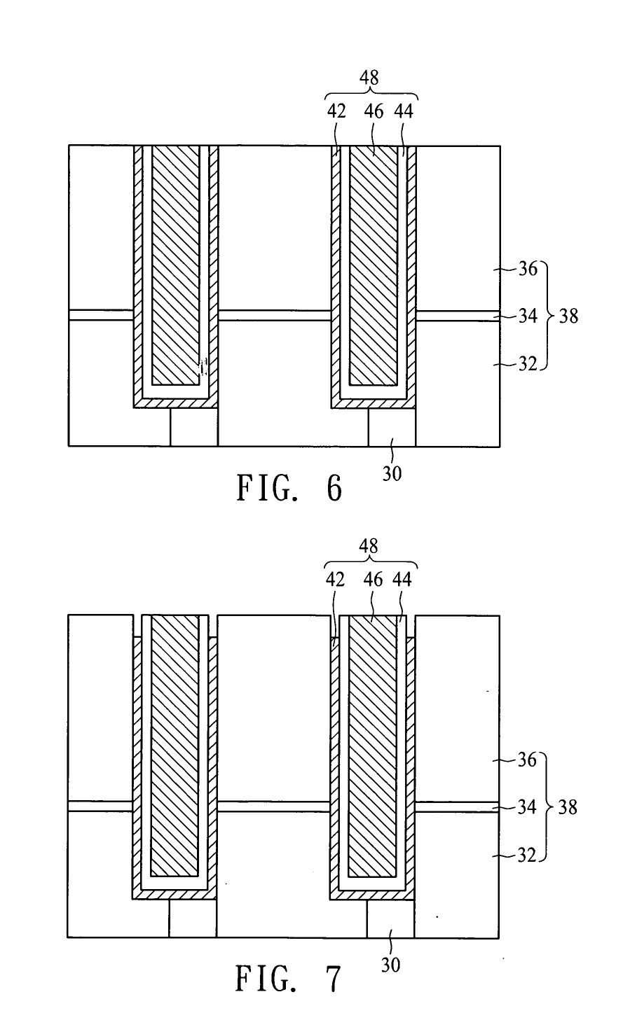

Referring to FIG. 5, a dielectric layer 44 is formed on the surfaces of the first conductive layer 42 and the silicon oxide layer 36, and a second conductive layer 46 is formed on the surface of the dielectric layer 44 by deposition process, wherein the second conductive layer 46 fills the circular opening 40. Subsequently, a planarization process, such as the chemical mechanical polishing (CMP) process, is performed to remove a portion of the dielectric layer 44 and the second conductive layer 46 from the surface of the silicon oxide layer 36 such that a cylindrical capacitor 48 is formed in the circular opening 40 in the dielectric structure 38, as shown in FIG. 6. Preferably, the dielectric layer 44 can be made of silicon oxide, silicon nitride, silicon oxynitride, aluminum oxide (Al₂O₃), hafnium oxide (HfO) or strontium titanate (SrTiO), while the second conductive layer 46 can be made of titanium nitride, tantalum nitride, ruthenium or doped polysilicon.

Referring to FIG. 7, a top portion of the first conductive layer 42 is removed such that a top end of the first conductive layer 42 is lower than that of the second conductive layer 46. Preferably, the first conductive layer 42 and the second conductive layer 46 are made of different materials, for example, the first conductive layer 42 is made of titanium nitride while the second conductive layer is made of doped polysilicon. The top portion of the first conductive layer 42 can be selectively removed by an etching process having an etching rate to the first conductive layer 42 higher than that to the second conductive layer 46. The etching process can be a dry etching process using tetrafluoromethane (CF₄)/nitrogen (N₂), chlorine (Cl₂)/argon or boron trichloride (BCl₃)/chlorine/trifluoromethane (CF₃H) as the etching gas.

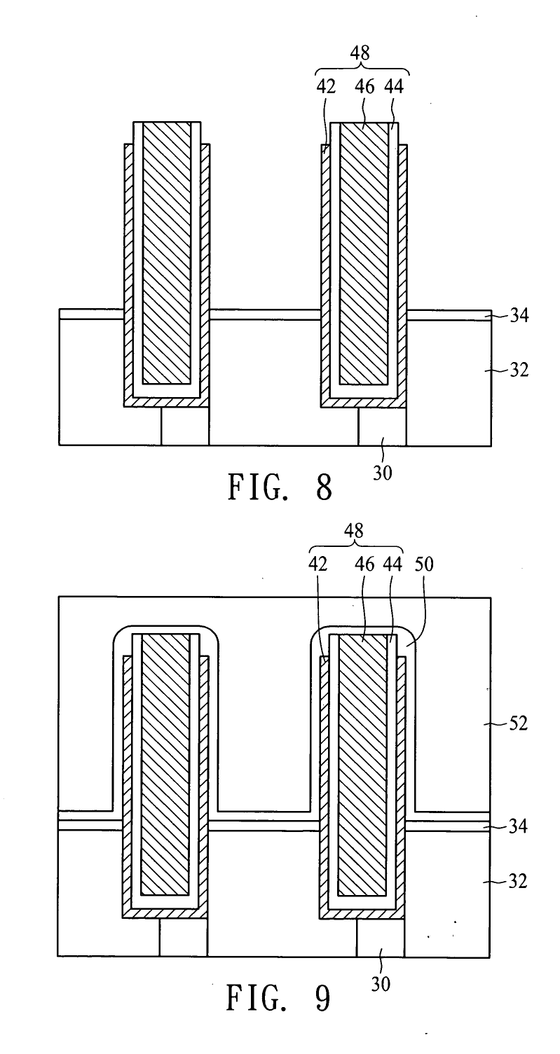

Referring to FIG. 8, a wet etching process using buffered fluoric acid as the etchant is performed to remove the silicon oxide layer 36 from the surface of the silicon nitride 34, i.e., removing a predetermined portion of the dielectric structure 38. Subsequently, a deposition process is performed to form a dielectric layer 50 covering the cylindrical capacitor 48 and the dielectric structure 38, and a spin-coating process is performed to form a spin-on dielectric layer 52 covering the dielectric layer 50, i.e., covering the cylindrical capacitor 48. Particularly, the processes in FIG. 7 to FIG. 9 are performed to electrically separate the first conductive layer 42 from the second conductive layer 46. Preferably, the dielectric layer 50 can be made of silicon oxide, silicon nitride, silicon oxynitride, aluminum oxide, hafnium oxide or strontium titanate, while the spin-on dielectric can be made of silicon oxide.

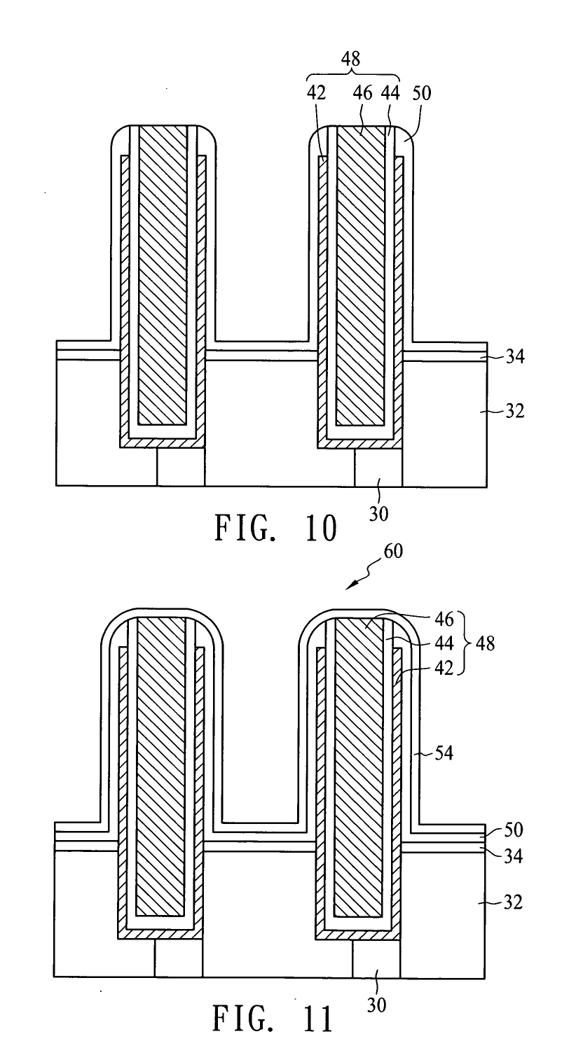

Referring to FIG. 10, a planarization process is performed to remove a portion of the dielectric layer 50 and the spin-on dielectric layer 52 above the top end of the cylindrical capacitor 48, and a wet etching process using buffered fluoric acid as the etchant is performed to remove the spin-on dielectric layer 52 on the side of the cylindrical capacitor 40. Particularly, the processes in FIG. 9 and FIG. 10 are performed to selectively remove a portion of the dielectric layer 50 from the second conductive layer 46 to expose the top end of the second conductive layer 46. Alternatively, a dry etching process can also selectively remove a portion of the dielectric layer 50 from the second conductive layer 46 to expose the top end of the second conductive layer 46. Subsequently, a deposition process is performed to form a third conductive layer 54 over the second dielectric layer 50 and the second conductive layer 46 to complete the capacitor structure 60. The third conductive layer 54 electrically connects with the exposed top end of the second conductive layer 46, as shown in FIG. 11.

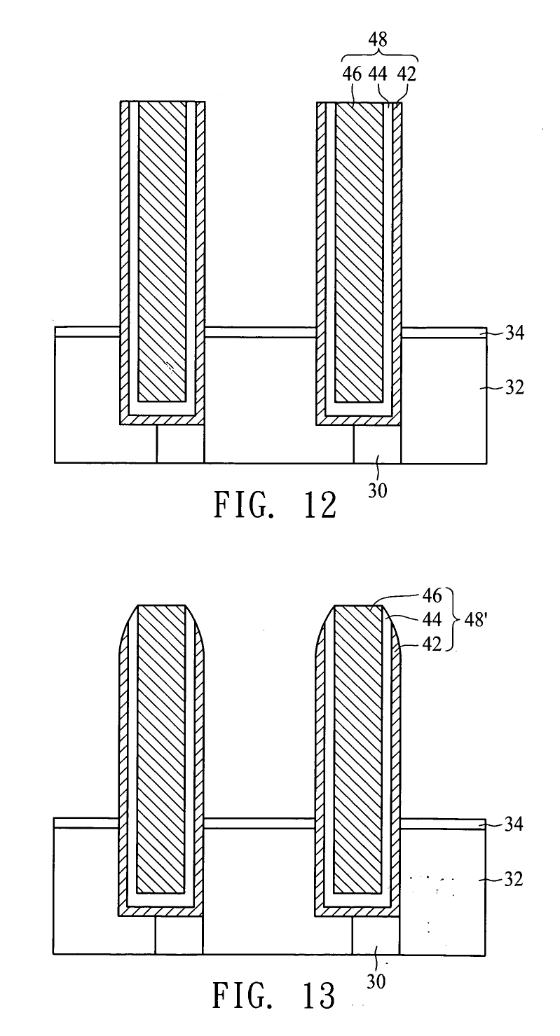

FIG. 12 to FIG. 15 illustrate a method for preparing a capacitor structure 70 according to a second embodiment of the present invention. The processes in FIG. 3 to FIG. 6 are performed, and a wet etching process using buffered fluoric acid as the etchant is performed to remove the silicon oxide layer 36 from the surface of the silicon nitride layer 34, i.e., removing a predetermined portion of the dielectric structure 38 to expose a portion of the cylindrical capacitor 48. Subsequently, a dry etching process is performed to remove the top portion of the first conductive layer 42 such that a cylindrical capacitor 48′ having a spacer profile is formed and the top end of the first conductive layer 42 is lower than that of the second conductive layer 46, as shown in FIG. 13. Preferably, the first conductive layer 42 and the second conductive layer 46 are made of different materials. The etching gas of the dry etching process may be carbon tetrachloride/oxygen, tetrafluoromethane/nitrogen, chlorine/argon or boron trichloride/chlorine/trifluoromethane.

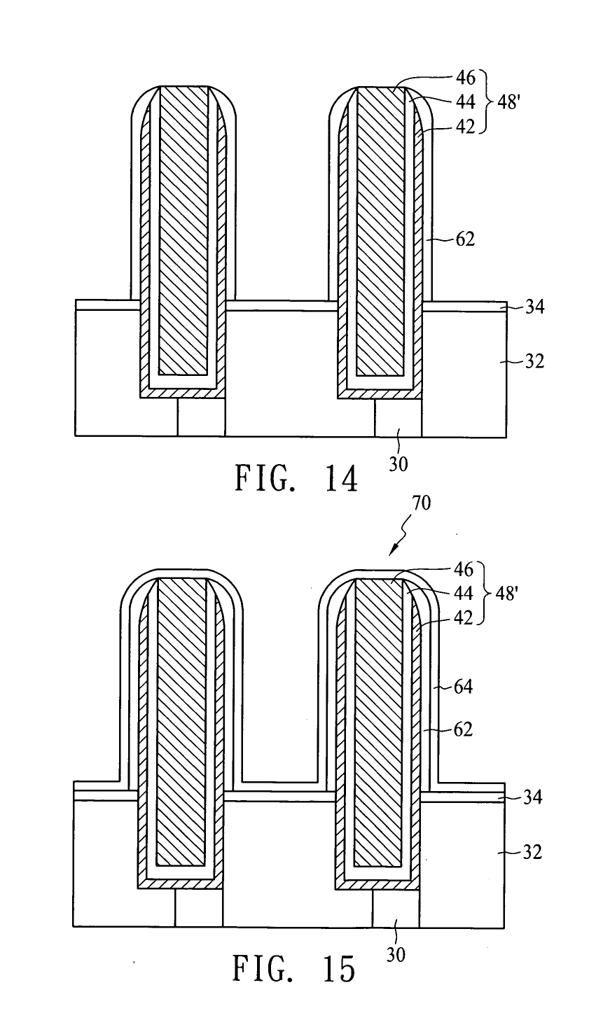

Referring to FIG. 14, a deposition process is performed to form a dielectric layer 62 covering the cylindrical capacitor 48′ and the dielectric structure 38. The processes in FIG. 13 and FIG. 14 are performed to electrically separate the first conductive layer 42 from the second conductive layer 46. Subsequently, a dry etching process is performed to remove a portion of the dielectric layer 62 from the surface of second conductive layer 46 so as to expose the top end of the second conductive layer 46, and a deposition process is then performed to form a third conductive layer 64 electrically connected to the exposed top end of the second conductive layer 46 to complete the capacitor structure 70, as shown in FIG. 15. Furthermore, removing a portion of the dielectric layer 62 from the surface of the second conductive layer 46 may also be achieved by the processes shown in FIG. 9 and FIG. 10.

The conventional hollow semicrown-shaped capacitor 22 is likely to lean or even collapse due to insufficient mechanical supporting strength during the fabrication process. In contrast, the method disclosed in the above embodiments of the present invention can form the solid cylindrical capacitors 48 and 48′ in the capacitor structures 60 and 70, respectively. Since the cylindrical capacitors 48 and 48′ are solid cylinders filling the circular opening 40 in the dielectric structure 38, they still possess enough mechanical supporting strength after a predetermined portion of the dielectric structure 38 is removed, as shown in FIG. 8. Consequently, the solid cylindrical capacitors 48 and 48′ will not lean or collapse during the subsequent fabrication process. The method of the present invention is suitable for application to the high integrity fabrication process.

The above-described embodiments of the present invention are intended to be illustrative only. Numerous alternative embodiments may be devised by those skilled in the art without departing from the scope of the following claims.

What is claimed is:

1. A method for preparing a capacitor structure of a semiconductor memory, comprising the steps of:
forming an opening in a dielectric structure;
forming a cylindrical capacitor in the opening, comprising:
forming a first conductive layer on a sidewall of the opening;
forming a first dielectric layer on a surface of the first conductive layer; and
forming a second conductive layer on a surface of the first dielectric layer;
electrically separating the first conductive layer from the second conductive layer; and
forming a third conductive layer electrically connected with a top portion of the second conductive layer.

2. The method for preparing a capacitor structure of a semiconductor memory of claim 1, wherein the cylindrical capacitor is a solid cylinder filling the opening.

3. The method for preparing a capacitor structure of a semiconductor memory of claim 1, wherein the step of electrically separating the first conductive layer from the second conductive layer comprises a step of removing a top portion of the first conductive layer, and thereby a top end of the first conductive layer is lower than that of the second conductive layer.

4. The method for preparing a capacitor structure of a semiconductor memory of claim 3, wherein the first conductive layer and the second conductive layer are made of different materials, and the top portion of the first conductive layer is removed by an etching process having an etching rate to the first conductive layer higher than that to the second conductive layer.

5. The method for preparing a capacitor structure of a semiconductor memory of claim 3, further comprising the following steps after the top portion of the first conductive layer is removed:
removing a predetermined portion of the dielectric structure;
forming a second dielectric layer on surfaces of the cylindrical capacitor and the dielectric structure;
removing a portion of the second dielectric layer from the second conductive layer; and
forming the third conductive layer on the second dielectric layer and the second conductive layer.

6. The method for preparing a capacitor structure of a semiconductor memory of claim 5, wherein the dielectric structure includes a silicon nitride layer and an oxide layer on the silicon nitride layer, and the step of removing a predetermined portion of the dielectric structure includes an etching process using an etchant including hydrofluoric acid to remove the oxide layer on the silicon nitride layer.

7. The method for preparing a capacitor structure of a semiconductor memory of claim 5, wherein the portion of the second dielectric layer is removed from the second conductive layer by a dry etching process.

8. The method for preparing a capacitor structure of a semiconductor memory of claim 5, wherein the step of removing a portion of the second dielectric layer from the second conductive layer comprises:
forming a spin-on dielectric layer covering the cylindrical capacitor;
performing a planarization process to remove a portion of the spin-on dielectric layer and the second dielectric layer from the cylindrical capacitor; and
performing a wet etching process to remove the spin-on dielectric layer.

9. The method for preparing a capacitor structure of a semiconductor memory of claim 3, wherein the step of removing a top portion of the first conductive layer comprises:
removing a predetermined portion of the dielectric structure; and
performing a dry etching process to remove the top portion of the first conductive layer, and thereby a spacer profile is formed on a top portion of the cylindrical capacitor.

10. The method for preparing a capacitor structure of a semiconductor memory of claim 9, wherein the dielectric structure comprises a silicon nitride layer and an oxide layer on the silicon nitride layer, and the step of removing a predetermined portion of the dielectric structure includes an etching process using an etchant including hydrofluoric acid to remove the oxide layer on the silicon nitride layer.

11. The method for preparing a capacitor structure of a semiconductor memory of claim 9, further comprising the following steps after the spacer profile is formed on the top portion of the cylindrical capacitor:
forming a second dielectric layer on surfaces of the cylindrical capacitor and the dielectric structure;
removing a portion of the second dielectric layer from the second conductive layer; and
forming the third conductive layer on the second dielectric layer and the second conductive layer.

12. The method for preparing a capacitor structure of a semiconductor memory of claim 11, wherein the portion of the second dielectric layer is removed from the second conductive layer by an etching process.

13. The method for preparing a capacitor structure of a semiconductor memory of claim 11, wherein the step of removing a portion of the second dielectric layer from the second conductive layer comprises:
forming a spin-on dielectric layer covering the cylindrical capacitor;
performing a planarization process to remove portions of the spin-on dielectric layer and the second dielectric layer from the cylindrical capacitor; and
performing a wet etching process to remove the spin-on dielectric layer.

14. A method for preparing a capacitor structure of a semiconductor memory, comprising the steps of:
forming an opening in a dielectric structure;
forming a cylindrical capacitor in the opening, comprising:
forming a first conductive layer on a sidewall of the opening;
forming a first dielectric layer on a surface of the first conductive layer; and
forming a second conductive layer on a surface of the first conductive layer, the second conductive layer filling the opening;
removing a top portion of the first conductive layer such that a top end of the first conductive layer is lower than that of the second conductive layer;
removing a predetermined portion of the dielectric structure;
forming a second dielectric layer on surfaces of the cylindrical capacitor and the dielectric structure;
removing a portion of the second dielectric layer from the second conductive layer; and
forming a third conductive layer on the second dielectric layer and the second conductive layer.

15. The method for preparing a capacitor structure of a semiconductor memory of claim 14, wherein the first conductive layer and the second conductive layer are made of different materials, and the top portion of the first conductive layer is removed by an etching process with an etching rate to the first conductive layer higher than that to the second conductive layer.

16. The method for preparing a capacitor structure of a semiconductor memory of claim 14, wherein the portion of the second dielectric layer is removed from the second conductive layer by a dry etching process.

17. The method for preparing a capacitor structure of a semiconductor memory of claim 14, wherein the step of removing a portion of the second dielectric layer from the second conductive layer comprises:
forming a third dielectric layer covering the cylindrical capacitor;
performing a planarization process to remove portions of the second and third dielectric layers from the cylindrical capacitor; and
removing the third dielectric layer.

18. A method for preparing a capacitor structure of a semiconductor memory, comprising the steps of:
forming an opening in a dielectric structure;
forming a cylindrical capacitor in the opening, comprising:
forming a first conductive layer on a sidewall of the opening;
forming a first dielectric layer on a surface of the first conductive layer; and
forming a second conductive layer on a surface of the first conductive layer, the second conductive layer filling the opening;
removing a predetermined portion of the dielectric structure;
performing a dry etching process to remove a top portion of the first conductive layer such that a spacer profile is formed on a top portion of the cylindrical capacitor and a top end of the first conductive layer is lower than that of the second conductive layer;
forming a second dielectric layer on surfaces of the cylindrical capacitor and the dielectric structure;
removing a portion of the second dielectric layer from the second conductive layer; and
forming a third conductive layer on the second dielectric layer and the second conductive layer.

19. The method for preparing a capacitor structure of a semiconductor memory of claim 18, wherein the portion of the second dielectric layer is removed from the second conductive layer by a dry etching process.

20. The method for preparing a capacitor structure of a semiconductor memory of claim 18, wherein the step of removing a portion of the second dielectric layer from the second conductive layer comprises:
forming a third dielectric layer covering the cylindrical capacitor;
performing a planarization process to remove portions of the second and third dielectric layers from the cylindrical capacitor; and
removing the third dielectric layer.
